(19) United States
(12) Patent Application Publication
(10) Pub. No.: US 2005/0104510 A1
(43) Pub. Date: May 19, 2005

(54) Organic light emitting device capable of white light emissions and method for making the same

(75) Inventors: Gautam Parthasarathy, Saratoga Springs, NY (US); Christian Maria Anton Heller, Albany, NY (US)

Correspondence Address: General Electric Company;Patrick K. Patnode, GE Global Research Center, Patent Docket Room 4A59, P.O. Box 8, Bldg. K-1, Schenectady, NY, 12301, US

(73) Assignee: General Electric Company

(21) Appl. No.: 10/712,093

(22) Filed: Nov. 14, 2003

(51) Int. Cl. H05B 33/00

(52) U.S. Cl. 313/504; 313/506

(57) ABSTRACT

The present invention is directed to an organic light emitting device capable of white light emissions and a method for making the same. According to one embodiment, the invention relates to an organic light emitting device capable of white light emissions, the device comprising at least one light emissive polymer and at least one small molecule material in two layers adjacent to each other, wherein the at least one small molecule material has a wide enough bandgap and a high enough electron mobility to function as both a hole blocking layer and an electron transport layer.

### BACKGROUND OF THE INVENTION

The present invention relates generally to the field of lighting and displays, and more particularly to an organic light emitting device capable of white light emissions and a method for making the same.

Electroluminescent (“EL”) devices, which may be classified as either organic or inorganic, are well known in the graphic display and imaging art. EL devices have been produced in different shapes for many applications. Inorganic EL devices need to be carefully fabricated on crystalline or polycrystalline substrates and thus may prove to be more expensive. On the other hand, organic light emitting devices (“OLEDs”), which have been developed more recently, offer the benefits of low activation voltage and high brightness in addition to simple manufacture, and thus the promise of more widespread application.

An OLED is typically a thin film structure formed on a substrate such as glass or transparent plastic. A light-emitting layer of an organic EL material and optional adjacent organic semiconductor layers are sandwiched between a cathode and an anode. The organic semiconductor layers may be either hole (positive charge)-injection or electron (negative charge)-injection layers and also comprise organic materials. The material for the light-emitting layer may be selected from many organic EL materials that emit light having different wavelengths. The light emitting organic layer may itself comprise multiple sublayers, each comprising a different organic EL material.

To obtain illumination-quality lighting based on organic electroluminescence, a number of solutions have been explored and proposed. For example, one solution utilizes closely arranged OLEDs emitting blue, green, and red light. These colors are mixed to produce white light. In a similar approach, people have achieved white light emissions by incorporating one or more different color fluorescent or phosphorescent dyes into a single OLED. Another approach involves the use of a blue OLED and down-conversion materials to convert some of the blue light into other colors.

However, none of the existing techniques are particularly effective in producing efficient, high accuracy white light. In addition, the use of multiple emissive species gives rise to differential aging of the components of the device with a consequent color change over time as the device ages.

These and other drawbacks exist in known systems and techniques.

### BRIEF SUMMARY OF THE INVENTION

The present invention is directed to an organic light emitting device capable of white light emissions and a method for making the same that overcome these and other drawbacks of known systems and methods.

According to one embodiment, the invention relates to an organic light emitting device capable of white light emissions, the device comprising at least one light emissive polymer and at least one small molecule material in two layers adjacent to each other, wherein the at least one small molecule material has a wide enough bandgap and a high enough electron mobility to function as both a hole blocking layer and an electron transport layer.

According to another embodiment, the invention relates to a method for making an organic light emitting device capable of white light emissions, the method comprising forming a bi-layer comprising a light emissive polymer and a small molecule material in two layers adjacent to each other, wherein the small molecule material has a wide enough bandgap and a high enough electron mobility to function as both a hole-blocking layer and an electron transport layer, and incorporating the bi-layer into an organic light emitting device.

### BRIEF DESCRIPTION OF THE DRAWINGS

In order to facilitate a fuller understanding of the present invention, reference is now made to the appended drawings, in which like elements are referenced with like numerals. These drawings should not be construed as limiting the present invention, but are intended to be exemplary only.

FIG. 1 is a flow chart illustrating an exemplary method for making an organic light emitting device according to an embodiment of the invention.

FIG. 2 illustrates a cross-sectional view of an organic light emitting device according to an exemplary embodiment of the invention.

FIG. 3 illustrates a cross-sectional view of another organic light emitting device according to an exemplary embodiment of the invention.

FIG. 4 shows a white light spectrum from the exemplary device shown in FIG. 3.

FIG. 5 shows the current-density-voltage characteristics of four display pixels according to an exemplary embodiment of the invention.

FIG. 6 shows the power efficiency characteristics of four display pixels according to an exemplary embodiment of the invention.

### DETAILED DESCRIPTION OF THE INVENTION

Reference will now be made in detail to the present embodiments of the invention, examples of which are illustrated in the accompanying drawings.

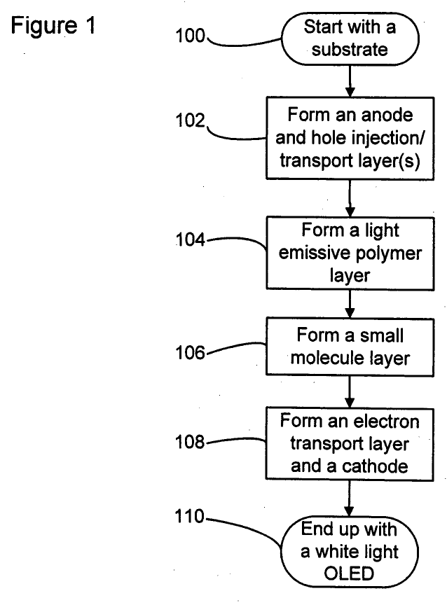

FIG. 1 is a flow chart illustrating an exemplary method for making an organic light emitting device according to an embodiment of the invention.

The exemplary method starts at step 100, where a substrate may be provided. The substrate may be made of a substantially transparent glass or polymeric material, for example. Examples of suitable polymeric materials include polyethylene terephthalate (PET), polyacrylates, polycarbonates, polyesters, polysulfones, polyetherimides, silicone, epoxy resins, and silicone-functionalized epoxy resins. In addition, an opaque substrate such as metal foils may be used, if a transparent top electrode (cathode) is chosen, for example.

At step 102, an anode and an optional hole injection layer and/or hole transport layer may be formed on top of the substrate. A typical anode layer may comprise indium tin oxide (ITO) or aluminum doped zinc oxide (AZO), for example, though other materials known in the art may also be used. The transparent anode materials may be formed, for example, in a physical vapor deposition (PVD) process or other suitable process. For example, ITO may be sputtered onto the substrate to form the anode layer. The anode material may be patterned either by using a shadow mask during deposition or via photolithographic steps after the deposition, for example.

According to embodiments of the invention, it may also be desirable to form additional layers, such as an optional hole injection layer and/or hole transport layer, on top of the anode. A hole injection layer may serve to improve the efficiency of hole injections from the anode. Suitable materials for the hole injection layer include polyethylenedioxythiophene (PDOT), copper phthalocyanine (CuPc), 4,4′,4″-tris {N,-(3-methylphenyl)-N-phenylamino}triphenylamine (m-MTDATA), and arylene-based compounds such as 3,4,9,10-perylenetetra-carboxylic dianhydride or bis(1,2,5-thiadiazolo)-p-quinobis(1,3-dithiole), for example. A hole transport layer may be disposed between the hole injection layer and a subsequent organic light emissive layer. The hole transport layer may have the functions of transporting holes and blocking the transportation of electrons so that holes and electrons may be combined in or near the organic light emissive layer. Materials suitable for the hole transport layer include, for example, triaryldiamine, tetraphenyldiamine, aromatic tertiary amines, hydrazone derivatives, carbazole derivatives, triazole derivatives, imidazole derivatives, oxadiazole derivatives having an amino group, polythiophenes, and N,N′-diphenyl-N,N′-bis(1-naphthylphenyl)-1,1′-biphenyl-4,4′-diamine (α-NPD). The organic hole injection layer and/or hole transport layer may be formed in a solution-cast process. According to one embodiment, a PDOT layer approximately 65 nanometers thick may be incorporated.

At step 104, a light emissive polymer layer may be formed on top of the aforementioned layers. The light emissive polymer may comprise a polyfluorene (PF)-based blue emissive polymer, for example. According to one embodiment of the invention, the light emissive polymer may comprise a high-efficiency polyfluorene-based blue emissive polymer. Other light emissive polymer materials, such as poly(p-phenylene vinylenes), polyphenylenes, polythiophene, polyquinolines, polyfluorenes, poly(vinylcarbazole), polystyrene with quaterphenylene segments, poly(disilanyleneoligothienylene), and their derivatives and mixtures, may also be used. The light emissive polymer layer may be formed in a solution-cast process. For example, a solution may be prepared by dissolving the light emissive polymer into a suitable solvent. Then the solution may be spin-cast onto the sample, causing a uniform layer of the light emissive polymer to be deposited. According to one exemplary embodiment, the polyfluorene-based blue light emissive polymer layer may be approximately 70 nanometers thick. Other processing techniques may also be used to form the light emissive polymer layer.

At step 106, a distinct layer of small molecule material may be formed on top of the light emissive polymer layer. According to embodiments of the invention, it may be desirable to choose a small molecule material that has a wide bandgap, a high electron mobility and a LUMO (Lowest Unoccupied Molecular Orbital) value that has a minimal or small offset from the LUMO values of the two neighboring layers, such that it may function as both a hole-blocking layer and an electron transport layer. For example, the bandgap may be larger than the emissive blue layer by 0.5 to 2 eV. The electron mobility may be larger than 10⁻⁵ cm²/Vs at an electric field of 0.5 MV/cm, for example. The high electron mobility and a matching LUMO (preferably between the LUMOs of neighboring layers) may facilitatc efficient transport of electrons and the wide bandgap may provide effective blocking of holes. As a result, some fraction of the injected carriers (i.e., electrons and holes) may form an excited state complex at or near the interface of the light emissive polymer and the small molecule material. This excited state complex may be referred to as an “exciplex” and typically features broad emissions deep into the red. One suitable small molecule material is bathocuproine (BCP), a commercially available material, with a bandgap of approximately 3.5 eV and an electron mobility of approximately 10⁻³ cm² Vs. The layer of small molecule material such as BCP may be formed by thermal evaporation, for example. According to one embodiment, the BCP layer may have a thickness between 60 and 150 angstroms. Other hole-blocking materials, such as 3-(4-biphenylyl)-4-phenyl-5(4-tert-butylpheny)-1,2,4-triazole (TAZ) and 2-(4′-tert-bytylphenyl)-5-(4′-diphenyl)-1,3,4-oxadiazole (PBD) may also be utilized in place of BCP.

At step 108, an optional electron transport layer, and a cathode may be formed on top of the small molecule material layer. The electron transport layer may facilitate efficient transport of electrons from the cathode into the electroluminescent core of the OLED device. Materials suitable for the electron transport layer include, for example, metal organic complexes of 8-hydroxyquinoline, such as tris(8-quinolinolato)aluminum, stilbene derivatives, anthracene derivatives, perylene derivatives, metal thioxinoid compounds, oxadiazole derivatives and metal chelates, pyridine derivatives, pyrimidine derivatives, quinoline derivatives, quinoxaline derivatives, diphenylquinone derivatives, nitro-substituted fluorene derivatives, triazines, and triazoles, chemically or electrically doped layers, e.g., with alkali metals. According to an embodiment of the invention, an approximately 250-angstrom thick tris(8-hydroxy-quinoline)aluminum (Alq₃) layer may be formed in a thermal evaporation process. According to another embodiment, a white light OLED may be fabricated without an Alq₃ layer.

The cathode layer may comprise a material having a low work function, e.g., less than about 4 eV, such as K, Li, Na, Mg, La, Ce, Ca, Sr, Ba, Al, Ag, In, Sn, Zn, Zr, Sm, Eu, alloys thereof, or mixtures thereof. Layered non-alloy structures may also be used, such as a thin layer of a metal such as Ca (thickness from about 1 to about 10 nm, for example) or a non-metal such as sodium fluoride (NaF) or lithium fluoride (LiF), covered by a thicker layer of some other metal, such as aluminum (Al) or silver (Ag). With a bi-layer cathode of Al/NaF or Al/LiF, a higher electroluminescence efficiency, external quantum efficiency and electron injection efficiency may be achieved than with a single-metal cathode.

According to one exemplary embodiment, the cathode may comprise a 7-100 angstroms thick NaF layer or a 7 angstroms thick LiF layer, covered by a thick Al layer. The NaF or LiF layer may be formed in a chemical vapor deposition (CVD) process and the subsequent Al layer may be formed in an evaporation process, for example. The cathode layer(s) may be patterned depending on intended applications of the OLED.

The exemplary method ends at step 110, where a white light OLED with the above-described multilayer structure has been fabricated. Additional configuration and packaging steps may be utilized to create a final product. It should be noted that the above-described method steps may be applicable to the manufacture of both single devices and integrated systems in which a plurality of same or similar OLEDs as well as control circuitry may be combined.

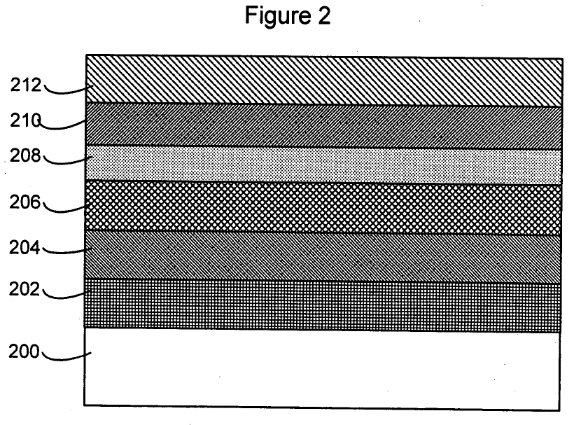

FIG. 2 illustrates a cross-sectional view of an organic light emitting device according to an exemplary embodiment of the invention. As shown in FIG. 2, the OLED may comprise a substrate 200, an anode 202, an optional hole injection and/or hole transport layer 204, a light emissive polymer layer 206, a small molecule material layer 208, an optional electron transport layer 210, and a cathode 212. Although all the layers are shown to have the same shape, they may have different shapes, patterns and/or thicknesses depending on specific requirements in different applications. For example, in OLED display applications, the anode 202 and the cathode 212 may be patterned into bus lines to accommodate efficient addressing of individual display elements.

By applying a DC voltage between the anode 202 and the cathode 212, electrons and holes are injected and transported through the electron transport layer 210 and the hole transport layer 204, respectively. The electrons and holes may recombine, at or near the interface between the light emissive polymer layer 206 and the small molecule material layer 208, to form an excited state complex or exciplex. The exciplex may subsequently give rise to white light emissions.

The exemplary device produces white light as a result of the blue emission from the polyfluorene-based polymer and the red emission from the exciplex formed at the interface with the small molecule BCP. The sum of these two spectra is broad and provides for a high accuracy white light. It should be appreciated that embodiments of the invention may comprise a hybrid between a thermally evaporated small molecule material and a solution-processed light emissive polymer, and that the shared excited state exists at or near the interface between the two materials. The small molecule and polymer materials constitute two distinct layers and are not blended according to exemplary embodiments of the invention.

Due to the voltage tunable exciplex emissions, this type of OLED can provide for color tuning. For example, by varying the applied voltage between the electrodes, the prominent peak in the emission spectrum may be accurately shifted to different wavelengths. As a result, the emission color of the OLEDs may be not only white but other colors (e.g., blue or purple) as well, depending on the applied voltage. These advantages may make this type of OLED attractive for applications where different correlated color temperatures (CCTs) are needed at different times. An OLED in accordance with embodiments of the present invention may be used as a tunable white light bulb. In addition, since there is only one emissive species according to exemplary embodiments of the invention, differential aging of the devices is typically not a concern. Other applications may include, for example, electronic display boards, traffic lights and color signs.

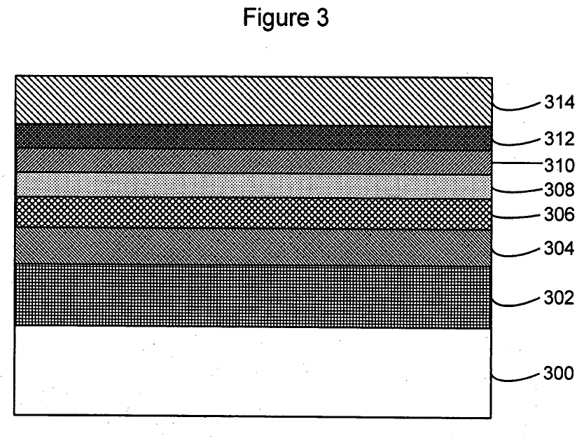

FIG. 3 illustrates a cross-sectional view of another organic light emitting device according to an exemplary embodiment of the invention. This OLED device comprises a glass substrate 300, an ITO anode 302, a PDOT layer 304 as a hole injection layer, a polyfluorene-based blue light emissive polymer layer 306, a BCP layer 308, an Alq₃ layer 310 as an electron transport layer, and a cathode comprising a NaF layer 312 and an Al layer 314. Experiments were conducted to examine the characteristics of this structure in producing illumination quality white light.

A number of configurations were tested for the device shown in FIG. 3. For example, the thickness of the BCP layer 308 was varied between 60 and 150 angstroms and the thickness of the NaF layer 312 was varied between 7 and 40 angstroms. In a few test samples, the NaF layer 312 was replaced with a LiF layer approximately 7 angstroms thick. A DC voltage of 6.0 volts was applied between the ITO anode 302 and the Al layer 314.

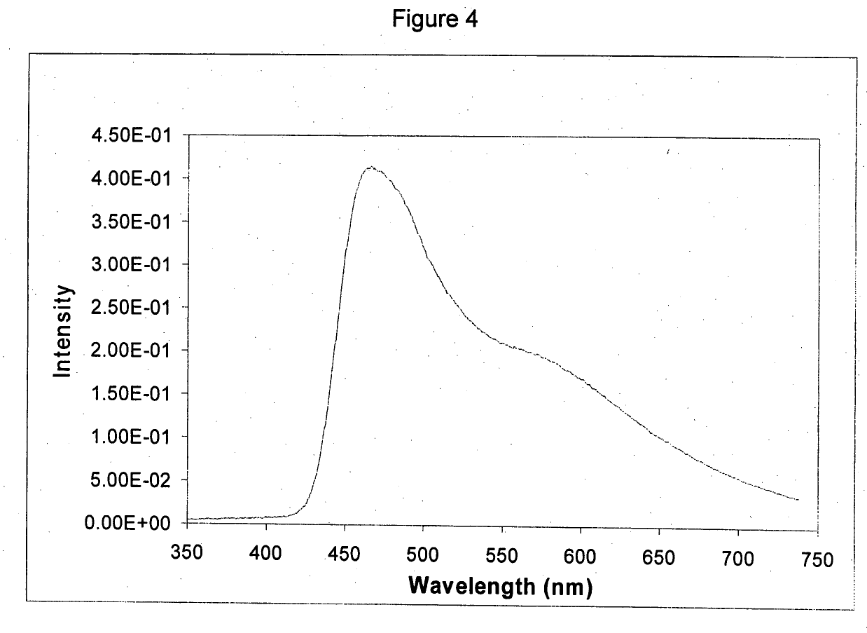

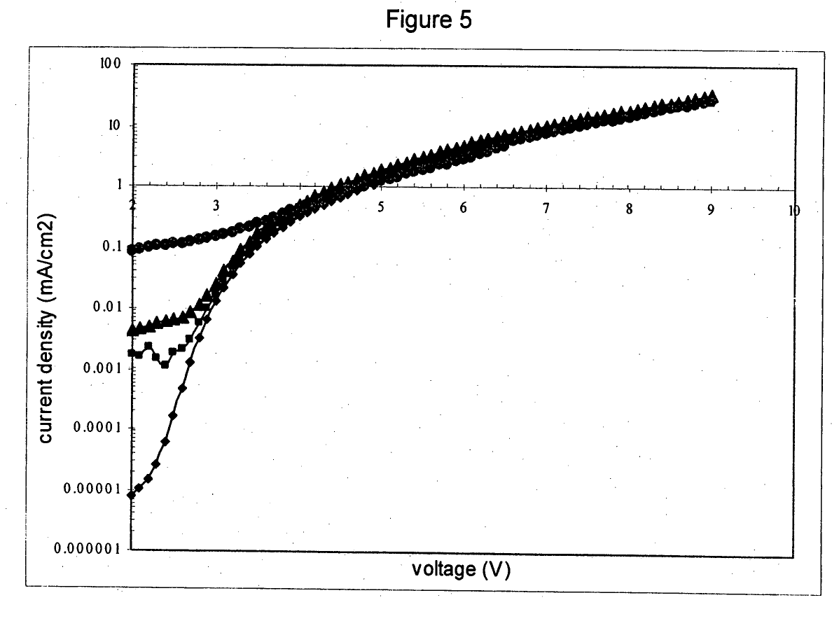

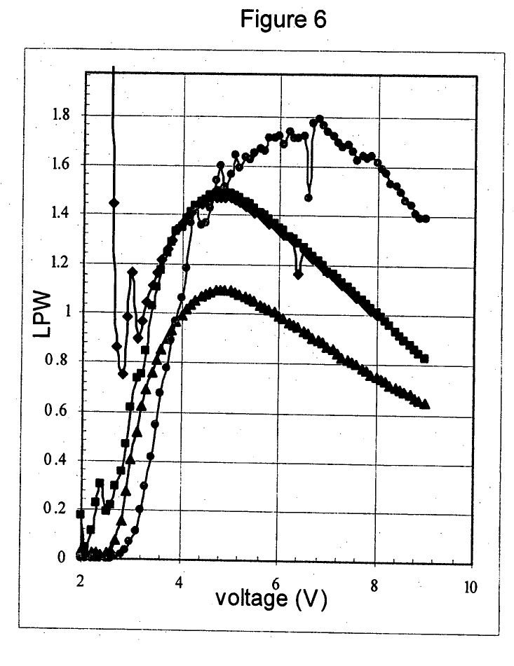

The resulting exciplex emission, as well as the device characteristics, were measured at drive current densities ranging from 200 μA/cm² to 200 mA/cm². FIG. 4 shows a representative white light spectrum from the device shown in FIG. 3. FIG. 5 shows the current-density-voltage characteristics of four display pixels fabricated on one substrate, each pixel having a similar structure to that shown in FIG. 3. FIG. 6 shows the power efficiency characteristics of the four display pixels. As shown FIGS. 5 and 6, the four pixels exhibited some variations in their performance. These variations may be attributed to variations in the fabrication process. For example, one or more layers may have been deposited non-uniformly to some extent over the substrate. Temperature changes in the process may cause one part of a film to have a different amount of stress from another part. These and other factors may cause some differences in the characteristics of devices on the same substrate.

The exciplex emission was peaked at approximately 633 nanometers with a 120-nanometer full width at half maximum. The device, as a light source, typically had a high color rendering index (CRI) of 80-95 with a correlated color temperature (CCT) of 6000-8000 Kelvin. The colors of the OLED light were measured as being centered around (0.3, 0.3) on the Commission Internationale d'Eclairage (CIE) color chart, which means the emissions were substantially white. The testing results confirmed that these OLEDs were capable of illumination-quality white light emissions. The efficiency for the devices to convert electrical power into optical power was also measured in terms of LPWR (lumens per watt ratio). The LPWR ranges from 228 to 366.

While the foregoing description includes many details and specificities, it is to be understood that these have been included for purposes of explanation only, and are not to be interpreted as limitations of the present invention. It will be apparent to those skilled in the art that other modifications to the embodiments described above can be made without departing from the spirit and scope of the invention. Accordingly, such modifications are considered within the scope of the invention as intended to be encompassed by the following claims and their legal equivalents.

1. An organic light emitting device capable of white light emissions, the device comprising at least one light emissive polymer and at least one small molecule material in two layers adjacent to each other, wherein the at least one small molecule material has a wide enough bandgap and a high enough electron mobility to function as both a hole blocking layer and an electron transport layer.

2. The organic light emitting device according to claim 1, wherein the at least one light emissive polymer comprises a polyfluorene-based blue light emissive polymer.

3. The organic light emitting device according to claim 1, wherein the at least one small molecule material has a lowest unoccupied molecular orbital (LUMO) value between the LUMO values of two adjacent layers of the at least one small molecule material.

4. The organic light emitting device according to claim 1, wherein the at least one small molecule material comprises bathocuproine (BCP).

5. The organic light emitting device according to claim 1, wherein the at least one light emissive polymer is formed by a solution-cast process and the at least one small molecule material is formed by an evaporation process.

6. The organic light emitting device according to claim 1, wherein the device has a multilayer structure on a substrate, the multilayer structure comprising a plurality of layers starting from the substrate in the following order:
(a) an anode;
(b) at least one hole injection layer or hole transport layer;
(c) the at least one light emissive polymer;
(d) the at least one small molecule material;
(e) one or more electron transport layers; and
(f) a cathode.

7. The organic light emitting device according to claim 1, wherein the device has a multilayer structure on a substrate, the multilayer structure comprising a plurality of materials starting from the substrate in the following order:
(a) indium tin oxide (ITO);
(b) polyethylenedioxythiophene (PDOT);
(c) A polyfluorene-based blue light emissive polymer;
(d) bathocuproine (BCP);
(e) tris(8-hydroxy-quinoline)aluminum (Alq₃);
(f) sodium fluoride (NaF) or lithium fluoride (LiF); and
(g) aluminum (Al).

8. A method for making an organic light emitting device capable of white light emissions, the method comprising:
forming a bi-layer comprising a light emissive polymer and a small molecule material in two layers adjacent to each other, wherein the small molecule material has a wide enough bandgap and a high enough electron mobility to function as both a hole-blocking layer and an electron transport layer; and
incorporating the bi-layer into an organic light emitting device.

9. The method according to claim 8, wherein the light emissive polymer comprises a polyfluorene-based blue light emissive polymer.

10. The method according to claim 8, wherein the small molecule material has a lowest unoccupied molecular orbital (LUMO) value between the LUMO values of two adjacent layers of the small molecule material.

11. The method according to claim 8, wherein the small molecule material comprises bathocuproine (BCP).

12. The method according to claim 8, wherein the light emissive polymer is formed by a solution-cast process and the small molecule material is formed by an evaporation process.

13. The method according to claim 8 further comprising forming a multilayer structure on a substrate, the multilayer structure comprising a plurality of layers starting from the substrate in the following order:
(a) an anode;
(b) at least one hole injection layer hole transport layer;
(c) the at least one light emissive polymer;
(d) the at least one small molecule material;
(e) one or more electron transport layers; and
(f) a cathode.

14. The method according to claim 8 further comprising forming a multilayer structure on a glass substrate, the multilayer structure comprising a plurality of materials starting from the glass substrate in the following order:
(a) indium tin oxide (ITO);
(b) polyethylenedioxythiophene (PDOT);
(c) a polyfluorene-based blue light emissive polymer;
(d) bathocuproine (BCP);
(e) tris(8-hydroxy-quinoline)aluminum (Alq₃);
(f) sodium fluoride (NaF) or lithium fluoride (LiF); and
(g) aluminum (Al).
